(19) United States
(12) Patent Application Publication
(10) Pub. No.: US 2025/0212325 A1
(43) Pub. Date: Jun. 26, 2025

(54) Laminate for a Printed Circuit Board

(71) Applicant: Ticona LLC, Florence, KY (US)

(72) Inventors: Xiaowei Zhang, Union, KY (US); Sean Culligan, Zionsville, IN (US)

(21) Appl. No.: 18/976,410

(22) Filed: Dec. 11, 2024

Related U.S. Application Data
(60) Provisional application No. 63/612,388, filed on Dec. 20, 2023.

(51) Int. Cl. H05K 1/03; C08G 63/60; C08J 5/24

(52) U.S. Cl. CPC H05K 1/0366; C08G 63/605; C08J 5/246; C08G 2250/00; C08J 2467/04; H05K 2201/0141

(57) ABSTRACT

A laminate comprising a fibrous substrate and a conductive layer positioned adjacent to the fibrous substrate is provided. The fibrous substrate is formed from fibers that include a polymer composition. The polymer composition contains a liquid crystalline polymer, and it has a melting temperature of from about 300° C. to about 400° C. and a dissipation factor of about 0.005 or less at a frequency of 10 GHz.

### RELATED APPLICATION

The present application is based upon and claims priority to U.S. Provisional Patent Application Ser. No. 63/612,388, having a filing date of Dec. 20, 2023, which is incorporated herein by reference.

### BACKGROUND OF THE INVENTION

Printed circuit boards (PCBs) can be composed of various kinds of materials that provide the characteristic attributes necessary for the electrical and mechanical operation of products for different applications. For example, printed circuit boards typically contain a conductive layer (e.g., copper film) stacked together with a dielectric material. Pre-impregnated composites (“prepregs”) are often employed as the dielectric material in certain types of printed circuit boards (e.g., rigid or rigid-flex boards). For example, one prepreg that is commonly employed is known as FR-4, which is fabricated from a woven fiberglass cloth that is impregnated with an epoxy resin. While having certain beneficial properties, the fiberglass cloth tends to have a relatively high dielectric constant/dissipation factor and low mechanical strength, which limits its use in more advanced low loss laminates for high speed digital communications, such as at internet data centers, supercomputers, etc. As such, a need exists for an improved material for use in printed circuit boards, particularly those used in high speed digital communications.

### SUMMARY OF THE INVENTION

In accordance with one embodiment of the present invention, a laminate is disclosed that comprises a fibrous substrate and a conductive layer positioned adjacent to the fibrous substrate. The fibrous substrate is formed from fibers that include a polymer composition. The polymer composition contains a liquid crystalline polymer. Further, the composition has a melting temperature of from about 300° C. to about 400° C. as determined in accordance with ISO 11357-3:2018 and a dissipation factor of about 0.005 or less at a frequency of 10 GHz.

Other features and aspects of the present invention are set forth in greater detail below.

### BRIEF DESCRIPTION OF THE FIGURES

A full and enabling disclosure of the present invention, including the best mode thereof to one skilled in the art, is set forth more particularly in the remainder of the specification, including reference to the accompanying figures, in which:

FIG. 1 is a schematic view of one embodiment the laminate of the present invention;

FIG. 2 is a schematic view of another embodiment the laminate of the present invention;

FIG. 3 is a schematic view of yet another embodiment the laminate of the present invention;

FIG. 4 is a schematic view of one embodiment of a system for spinning a polymer composition into fibers; and

FIG. 5 is a schematic view of one embodiment of an electronic device that may employed a circuit board formed from the laminate of the present invention.

### DETAILED DESCRIPTION

It is to be understood by one of ordinary skill in the art that the present discussion is a description of exemplary embodiments only, and is not intended as limiting the broader aspects of the present invention.

Generally speaking, the present invention is directed to a laminate that contains a fibrous substrate formed from fibers that include a liquid crystalline polymer and a conductive layer positioned adjacent to the substrate. By selectively controlling the specific nature of the fibers and polymer composition from which they are formed, the resulting fibrous substrate can exhibit a unique combination of good electrical, thermal, and mechanical properties for use in a printed circuit board. For example, the polymer composition, fibers (and yarns), and fibrous substrates can exhibit a low dissipation factor (or loss rate of energy) over a wide range of frequencies, making it particularly suitable for use in 5G applications. The dissipation factor may, for instance, be about 0.005 or less, in some embodiments about 0.001 or less, and in some embodiments from about 0.0001 to about 0.0008 over typical 5G frequencies (e.g., 2 or 10 GHZ). The dielectric constant may also be low, such as of about 5 or less, in some embodiments about 4.5 or less, in some embodiments from about 1 to about 4, in some embodiments from about 1.5 to about 3.8, and in some embodiments, from about 2 to about 3.5, as determined by the split post resonator method over typical 5G frequencies (e.g., 2 GHz or 10 GHZ).

In addition to exhibiting good high frequency electrical properties, the polymer composition, fibers (and yarns), and fibrous substrate can also exhibit good thermal and mechanical properties to enable its use in forming fibers and fibrous substrates for printed circuit board laminates. The melting temperature of the composition may, for instance, be from about 300° C. to about 400° C., in some embodiments from about 305° C. to about 390° C., and in some embodiments, from about 310° C. to about 380° C. Even at such melting temperatures, the ratio of the deflection temperature under load (“DTUL”), a measure of short term heat resistance, to the melting temperature may still remain relatively high. For example, the ratio may range from about 0.6 to about 1.00, in some embodiments from about 0.65 to about 0.95, and in some embodiments, from about 0.7 to about 0.9. The specific DTUL values may, for instance, range from about 200° C. to about 350° C., in some embodiments from about 210° C. to about 320° C., and in some embodiments, from about 220° C. to about 290° C.

The tensile and flexural mechanical properties may also be good. For example, the polymer composition may exhibit a tensile strength of from about 50 to about 500 MPa, in some embodiments from about 100 to about 400 MPa, and in some embodiments, from about 150 to about 350 MPa; a tensile break strain of about 1.5% or more, in some embodiments from about 2% to about 10%, and in some embodiments, from about 2.5% to about 4.5%; and/or a tensile modulus of from about 4,000 MPa to about 20,000 MPa, in some embodiments from about 5,000 MPa to about 20,000 MPa, and in some embodiments, from about 6,000 MPa to about 20,000 MPa. The tensile properties may be determined at a temperature of about 23° C. in accordance with ISO 527:2019. The polymer composition may also exhibit a flexural strength of from about 20 to about 500 MPa, in some embodiments from about 50 to about 400 MPa, and in some embodiments, from about 100 to about 350 MPa; a flexural elongation of about 0.4% or more, in some embodiments from about 0.5% to about 10%, and in some embodiments, from about 0.6% to about 3.5%; and/or a flexural modulus of from about 4,000 MPa o about 20,000 MPa, in some embodiments from about 5,000 MPa to about 20,000 MPa, and in some embodiments, from about 6,000 MPa to about 15,000 MPa. The flexural properties may be determined at a temperature of about 23° C. in accordance with 178:2019.

Various embodiments of the present invention will now be described in more detail.

### 1. Polymer Composition

### A. Liquid Crystalline Polymer

The polymer composition used to form the fibers contains one or more liquid crystalline polymers. The liquid crystalline polymers are generally classified as “thermotropic” to the extent that they can possess a rod-like structure and exhibit a crystalline behavior in their molten state (e.g., thermotropic nematic state). The polymers may have a relatively high melting temperature and low melt viscosity, such as within the ranges described above. Such polymers may be formed from one or more types of repeating units as is known in the art. A liquid crystalline polymer may, for example, contain one or more aromatic ester repeating units generally represented by the following Formula (I):

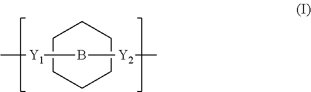

wherein,
ring B is a substituted or unsubstituted 6-membered aryl group (e.g., 1,4-phenylene or 1,3-phenylene), a substituted or unsubstituted 6-membered aryl group fused to a substituted or unsubstituted 5- or 6-membered aryl group (e.g., 2,6-naphthalene), or a substituted or unsubstituted 6-membered aryl group linked to a substituted or unsubstituted 5- or 6-membered aryl group (e.g., 4,4-biphenylene); and
Y₁ and Y₂ are independently O, C(O), NH, C(O)HN, or NHC(O).

Typically, at least one of Y₁ and Y₂ are C(O). Examples of such aromatic ester repeating units may include, for instance, aromatic dicarboxylic repeating units (Y₁ and Y₂ in Formula I are C(O)), aromatic hydroxycarboxylic repeating units (Y₁ is O and Y₂ is C(O) in Formula I), as well as various combinations thereof.

Aromatic hydroxycarboxylic repeating units, for instance, may be employed that are derived from aromatic hydroxycarboxylic acids, such as, 4-hydroxybenzoic acid; 4-hydroxy-4′-biphenylcarboxylic acid; 2-hydroxy-6-naphthoic acid; 2-hydroxy-5-naphthoic acid; 3-hydroxy-2-naphthoic acid; 2-hydroxy-3-naphthoic acid; 4′-hydroxyphenyl-4-benzoic acid; 3′-hydroxyphenyl-4-benzoic acid; 4′-hydroxyphenyl-3-benzoic acid, etc., as well as alkyl, alkoxy, aryl and halogen substituents thereof, and combination thereof. Particularly suitable aromatic hydroxycarboxylic acids are 4-hydroxybenzoic acid (“HBA”) and 6-hydroxy-2-naphthoic acid (“HNA”). Aromatic dicarboxylic repeating units may also be employed that are derived from aromatic dicarboxylic acids, such as terephthalic acid, isophthalic acid, 2,6-naphthalenedicarboxylic acid, diphenyl ether-4,4′-dicarboxylic acid, 1,6-naphthalenedicarboxylic acid, 2,7-naphthalenedicarboxylic acid, 4,4′-dicarboxybiphenyl, bis(4-carboxyphenyl)ether, bis(4-carboxyphenyl)butane, bis(4-carboxyphenyl)ethane, bis(3-carboxyphenyl)ether, bis(3-carboxyphenyl)ethane, etc., as well as alkyl, alkoxy, aryl and halogen substituents thereof, and combinations thereof. Particularly suitable aromatic dicarboxylic acids may include, for instance, terephthalic acid (“TA”), isophthalic acid (“IA”), and 2,6-naphthalenedicarboxylic acid (“NDA”).

Other repeating units may also be employed in the polymer. In certain embodiments, for instance, repeating units may be employed that are derived from aromatic diols, such as hydroquinone, resorcinol, 2,6-dihydroxynaphthalene, 2,7-dihydroxynaphthalene, 1,6-dihydroxynaphthalene, 4,4′-dihydroxybiphenyl (or 4,4′-biphenol), 3,3′-dihydroxybiphenyl, 3,4′-dihydroxybiphenyl, 4,4′-dihydroxybiphenyl ether, bis(4-hydroxyphenyl)ethane, etc., as well as alkyl, alkoxy, aryl and halogen substituents thereof, and combinations thereof. Particularly suitable aromatic diols may include, for instance, hydroquinone (“HQ”) and 4,4′-biphenol (“BP”). Repeating units may also be employed, such as those derived from aromatic amides (e.g., acetaminophen (“APAP”)) and/or aromatic amines (e.g., 4-aminophenol (“AP”), 3-aminophenol, 1,4-phenylenediamine, 1,3-phenylenediamine, etc.). It should also be understood that various other monomeric repeating units may be incorporated into the polymer. For instance, in certain embodiments, the polymer may contain one or more repeating units derived from non-aromatic monomers, such as aliphatic or cycloaliphatic hydroxycarboxylic acids, dicarboxylic acids, diols, amides, amines, etc. Of course, in other embodiments, the polymer may be “wholly aromatic” in that it lacks repeating units derived from non-aromatic (e.g., aliphatic or cycloaliphatic) monomers.

The specific monomers and molar concentrations of the liquid crystalline polymer(s) may be selected to help achieve the desired combination of electrical, thermal, and mechanical properties as discussed herein. For example, the liquid crystalline polymer may be a “high naphthenic” polymer to the extent that it contains a relatively high content of repeating units derived from naphthenic hydroxycarboxylic acids and naphthenic dicarboxylic acids, such as NDA, HNA, or combinations thereof. That is, the total amount of repeating units derived from naphthenic hydroxycarboxylic and/or dicarboxylic acids (e.g., NDA, HNA, or a combination of HNA and NDA) is typically about 10 mol. % or more, in some embodiments about 12 mol. % or more, in some embodiments about 15 mol. % or more, in some embodiments about 18 mol. % or more, in some embodiments about 30 mol. % or more, in some embodiments about 40 mol. % or more, in some embodiments about 45 mol. % or more, in some embodiments about 50 mol. % or more, in some embodiments about 60 mol. % or more, in some embodiments about 62 mol. % or more, in some embodiments about 68 mol. % or more, in some embodiments about 70 mol. % or more, and in some embodiments, from about 70 mol. % to about 80 mol. % of the polymer. Without intending to be limited by theory, it is believed that such “high naphthenic” polymers are capable of reducing the tendency of the polymer composition to absorb water, which can help stabilize the dielectric constant and dissipation factor at high frequency ranges. Namely, such high naphthenic polymers typically have a water adsorption of about 0.015% or less, in some embodiments about 0.01% or less, and in some embodiments, from about 0.0001% to about 0.008% after being immersed in water for 24 hours in accordance with ISO 62-1:2008. The high naphthenic polymers may also have a moisture adsorption of about 0.01% or less, in some embodiments about 0.008% or less, and in some embodiments, from about 0.0001% to about 0.006% after being exposed to a humid atmosphere (50% relative humidity) at a temperature of 23° C. in accordance with ISO 62-4:2008.

In one particular embodiment, for example, the liquid crystalline polymer may contain from 0 mol. % to about 5 mol. % of a repeating unit represented by Formula (I), from about 20 mol. % to about 70 mol. % of a repeating unit represented by Formula (II), from about 5 mol. % to about 50 mol. % of a repeating unit represented by Formula (III), from about 5 mol. % to about 50 mol. % of a repeating unit represented by Formula (IV), and from 0 mol. % to about 5 mol. % of a repeating unit represented by Formula (V):

—O—Ar¹—CO— (I)

—O—Ar²—CO— (II)

—CO—Ar³—CO— (III)

—O—Ar⁴—O— (IV)

—CO—Ar⁵—CO— (V)

wherein,
Ar¹, Ar⁴, and Ar⁵ independently represent a phenyl or a biphenyl group, optionally substituted with a halogen atom, an alkyl group having 1 to 10 carbon atoms, or an aryl group having 6 to 20 carbon atoms; and
Ar² and Ar³ independently represent a naphthenyl group optionally substituted with a halogen atom, an alkyl group having 1 to 10 carbon atoms, or an aryl group having 6 to 20 carbon atoms.

If desired, the molar ratio of the repeating unit represented by Formula (IV) (e.g., HQ and/or BP) to the total of repeating units represented by Formula (IIII) (e.g., NDA) and Formula (V) (e.g., TA and/or IA) may be from about 0.8 to about 1.5, and in some embodiments, from about 0.9 to about 1.3. In one particular embodiment, the ratio is about 1 such that the diol monomers are present in an equimolar amount to the dicarboxylic acid monomers to help achieve the desired properties of the polymer. Furthermore, while other monomeric constituents may certainly be employed, the total molar percentage of the repeating units represented by Formulae (I), (II), (III), (IV), and (V) may equal 100% in certain embodiments.

In particular embodiments, for example, the liquid crystalline polymer may contain from about 0.1 mol. % to about 5 mol. %, and in some embodiments, from about 0.5 mol % to about 4 mol. % of a repeating unit represented by Formula (I) (e.g., HBA); from about 35 mol. % to about 60 mol. %, and in some embodiments, from about 45 mol % to about 55 mol. % of a repeating unit represented by Formula (II) (e.g., HNA); from about 10 mol. % to about 40 mol. %, and in some embodiments, from about 15 mol % to about 30 mol. % of a repeating unit represented by Formula (III) (e.g., NDA); from about 10 mol. % to about 40 mol. %, and in some embodiments, from about 15 mol % to about 30 mol. % of a repeating unit represented by Formula (IV) (e.g., HQ and/or BP); and from about 0.1 mol. % to about 5 mol. %, and in some embodiments, from about 0.5 mol. % to about 4 mol. % of a repeating unit represented by Formula (V) (e.g., TA and/or IA).

Regardless of the particular constituents, the liquid crystalline polymer(s) may be prepared by initially introducing the aromatic monomer(s) used to form the ester repeating units (e.g., aromatic hydroxycarboxylic acid, aromatic dicarboxylic acid, etc.) and/or other repeating units (e.g., aromatic diol, aromatic amide, aromatic amine, etc.) into a reactor vessel to initiate a polycondensation reaction. The particular conditions and steps employed in such reactions are well known, and may be described in more detail in U.S. Pat. No. 4,161,470 to Calundann; U.S. Pat. No. 5,616,680 to Linstid, III, et al.; U.S. Pat. No. 6,114,492 to Linstid, III, et al.; U.S. Pat. No. 6,514,611 to Shepherd, et al.; and WO 2004/058851 to Waggoner. The vessel employed for the reaction is not especially limited, although it is typically desired to employ one that is commonly used in reactions of high viscosity fluids. Examples of such a reaction vessel may include a stirring tank-type apparatus that has an agitator with a variably-shaped stirring blade, such as an anchor type, multistage type, spiral-ribbon type, screw shaft type, etc., or a modified shape thereof. Further examples of such a reaction vessel may include a mixing apparatus commonly used in resin kneading, such as a kneader, a roll mill, a Banbury mixer, etc.

If desired, the reaction may proceed through the acetylation of the monomers as known the art. This may be accomplished by adding an acetylating agent (e.g., acetic anhydride) to the monomers. Acetylation is generally initiated at temperatures of about 90° C. During the initial stage of the acetylation, reflux may be employed to maintain vapor phase temperature below the point at which acetic acid byproduct and anhydride begin to distill. Temperatures during acetylation typically range from between 90° C. to 150° C., and in some embodiments, from about 110° C. to about 150° C. If reflux is used, the vapor phase temperature typically exceeds the boiling point of acetic acid, but remains low enough to retain residual acetic anhydride. For example, acetic anhydride vaporizes at temperatures of about 140° C. Thus, providing the reactor with a vapor phase reflux at a temperature of from about 110° C. to about 130° C. is particularly desirable. To ensure substantially complete reaction, an excess amount of acetic anhydride may be employed. The amount of excess anhydride will vary depending upon the particular acetylation conditions employed, including the presence or absence of reflux. The use of an excess of from about 1 to about 10 mole percent of acetic anhydride, based on the total moles of reactant hydroxyl groups present is not uncommon.

Acetylation may occur in in a separate reactor vessel, or it may occur in situ within the polymerization reactor vessel. When separate reactor vessels are employed, one or more of the monomers may be introduced to the acetylation reactor and subsequently transferred to the polymerization reactor. Likewise, one or more of the monomers may also be directly introduced to the reactor vessel without undergoing pre-acetylation. In addition to the monomers and optional acetylating agents, other components may also be included within the reaction mixture to help facilitate polymerization. For instance, a catalyst may be optionally employed, such as metal salt catalysts (e.g., magnesium acetate, tin (I) acetate, tetrabutyl titanate, lead acetate, sodium acetate, potassium acetate, etc.) and organic compound catalysts (e.g., N-methylimidazole). Such catalysts are typically used in amounts of from about 50 to about 500 parts per million based on the total weight of the recurring unit precursors. When separate reactors are employed, it is typically desired to apply the catalyst to the acetylation reactor rather than the polymerization reactor, although this is by no means a requirement.

The reaction mixture is generally heated to an elevated temperature within the polymerization reactor vessel to initiate melt polycondensation of the reactants. Polycondensation may occur, for instance, within a temperature range of from about 200° C. to about 400° C. For instance, one suitable technique for forming a liquid crystalline polymer may include charging precursor monomers and acetic anhydride into the reactor, heating the mixture to a temperature of from about 90° C. to about 150° C. to acetylize a hydroxyl group of the monomers (e.g., forming acetoxy), and then increasing the temperature to from about 200° C. to about 400° C. to carry out melt polycondensation. As the final polymerization temperatures are approached, volatile byproducts of the reaction (e.g., acetic acid) may also be removed so that the desired molecular weight may be readily achieved. The reaction mixture is generally subjected to agitation during polymerization to ensure good heat and mass transfer, and in turn, good material homogeneity. The rotational velocity of the agitator may vary during the course of the reaction, but typically ranges from about 10 to about 100 revolutions per minute (“rpm”), and in some embodiments, from about 20 to about 80 rpm. To build molecular weight in the melt, the polymerization reaction may also be conducted under vacuum, the application of which facilitates the removal of volatiles formed during the final stages of polycondensation. The vacuum may be created by the application of a suctional pressure, such as within the range of from about 5 to about 30 pounds per square inch (“psi”), and in some embodiments, from about 10 to about 20 psi.

The molten polymer may be discharged from the reactor at a point in which the desired melt viscosity is achieved. As is known in the art, this may be correlated to the torque of the agitator. For example, after the torque of the agitator reaches a predetermined value, nitrogen may be introduced into the reactor so as to convert reduced pressure conditions to pressurized conditions via atmospheric pressure, thereby discharging the resultant polymer from the reactor, typically through an extrusion orifice fitted with a die of desired configuration, cooled, and collected. Commonly, the melt is discharged through a perforated die to form strands that are taken up in a water bath, pelletized and dried.

Although not always required or desired, the melt polymerized polymer may also be subjected to a subsequent solid-state polymerization method to further increase its molecular weight and achieve the desired melt viscosity. Solid-state polymerization may be conducted in the presence of a gas (e.g., air, inert gas, etc.). Suitable inert gases may include, for instance, include nitrogen, helium, argon, neon, krypton, xenon, etc., as well as combinations thereof. The solid-state polymerization reactor vessel can be of virtually any design that will allow the polymer to be maintained at the desired solid-state polymerization temperature for the desired residence time. Examples of such vessels can be those that have a fixed bed, static bed, moving bed, fluidized bed, etc. The temperature at which solid-state polymerization is performed may vary, but is typically within a range of from about 300° C. to about 400° C. The polymerization time will of course vary based on the temperature and target molecular weight. In most cases, however, the solid-state polymerization time will be from about 2 to about 12 hours, and in some embodiments, from about 4 to about 10 hours.

### B. Additives

Liquid crystalline polymer(s) may be employed in neat form within a polymer composition (i.e., 100 wt. % of the polymer composition), or a wide variety of other additives may optionally be included within the composition. When employed, such additives typically constitute from about 1 wt. % to about 60 wt. %, in some embodiments from about 2 wt. % to about 50 wt. %, and in some embodiments, from about 5 wt. % to about 40 wt. % of the polymer composition. In such embodiments, liquid crystalline polymers may likewise constitute from about 40 wt. % to about 99 wt. %, in some embodiments from about 50 wt. % to about 98 wt. %, and in some embodiments, from about 60 wt. % to about 95 wt. % of the polymer composition. When employed, suitable additives may include, for instance, inorganic fillers, flow modifiers, lubricants, pigments (e.g., carbon black), antioxidants, stabilizers, surfactants, waxes, flame retardants, nucleating agents (e.g., boron nitride), electrically conductive fillers, and other materials added to enhance properties and processability.

### II. Fibers

The polymer composition described above is particularly suitable for forming fibers. As used herein, the term “fibers” generally encompasses a variety of types of fibers, including short fibers, continuous filaments, yarns, etc. Yarns may include, for instance, multiple staple filaments that are twisted together (“spun yarn”), filaments laid together without twist (“zero-twist yarn”), (3) filaments laid together with a degree of twist, (4) a single filament with or without twist (“monofilament”), etc. The yarn may or may not be texturized. The fibers may be used to form a portion or all of the yarn. The fibers and/or yarns may likewise be used to form a portion or all of a fibrous substrate (e.g., fabrics), such as a woven fabric, knit fabric, nonwoven fabric, etc. In certain embodiments, for instance, substantially all of the fibers of the yarn and/or fabric are formed in accordance with the present invention.

Any of a variety of different techniques may generally be employed to form fibers as is well known in the art. For example, the polymer composition may be extruded through a spinneret, optionally quenched, and drawn into a draw unit. In one particular embodiment, the polymer composition may be fed into an extruder from a hopper. The extruded composition can pass through a polymer conduit to a spinneret through which the fibers are melt spun. A quench blower may optionally be positioned adjacent the fibers extending from the spinneret that supplies air to quench the fibers. After any optional quenching, the fibers may be drawn into a draw unit, which may include an elongated vertical passage through which the fibers are drawn by aspirating air entering from the sides of the passage and flowing downwardly through the passage. The drawing or attenuation of the fibers can increase the molecular orientation or crystallinity of the polymer. After stretching, the fibers can optionally be heat-treated to enhance dimensional stability and crystallization, as well as further increasing the molecular weight of the liquid crystalline polymer within the polymer composition.

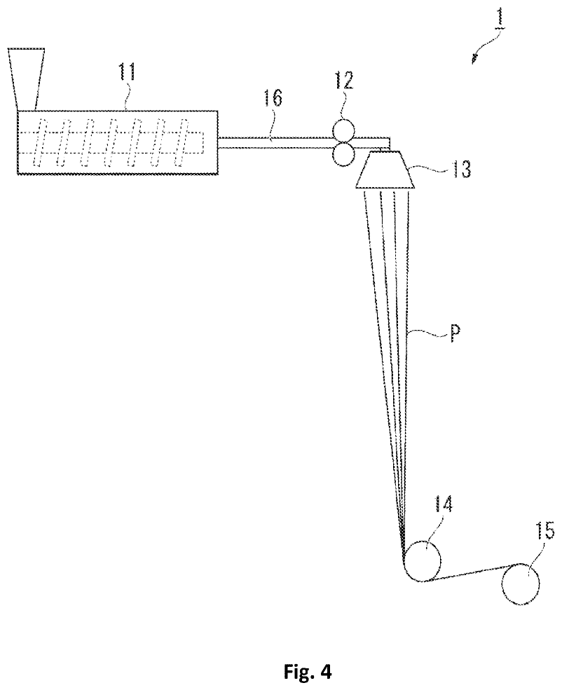

Referring to FIG. 4, for example, one embodiment of a system for forming fibers from the polymer composition is shown in more detail. In the illustrated embodiment, a spinning system 1 is show that has has an extruder 11 (e.g., single-screw, double-screw, etc.), gear pump 12, spinneret 13, drawing roller 14, winding roller 15, and resin channel 16. The extruder 11 and the spinneret may be connected to each other through the resin channel 16. The gear pump 12 may be provided in the middle of the resin channel 16. To form the fibers, the polymer composition may be initially heated to a temperature equal to or higher than the melting temperature of the composition. The melted liquid crystal polyester may then be transferred to the spinneret 13 with the gear pump 12, and extruded through the spinneret 13 to obtain a single fiber P. The spinneret 13 may contain one or more nozzles, each of which may have a diameter of from about 0.05 mm to about 0.20 mm, and in some embodiments, from about 0.07 mm to about 0.15 mm. The discharging amount of the polymer composition may, for example, be from about 1 to about 40 g/min, and in some embodiments, from about 10 to about 30 g/min. The shear rate at the spinneret may also be from about 10,000 s⁻¹ to about 100,000 s⁻¹, and in some embodiments, from about 30,000 s⁻¹ to about 80,000 s⁻¹ or less.

Following extrusion from the spinneret 13, the resulting fibers P may be drawn to assist with achieving certain properties, such as increasing amorphous orientation, shrinkage, modulus, and/or strength. However, it should be understood that in certain embodiments, drawing may not be conducted such that the fibers are undrawn. When conducted, drawing can be done in combination with take-up by using a series of rollers or pins (e.g., godet rollers), some of which may be heated, or it can be done as a separate stage in the process of the fiber formation. In the illustrated embodiment, for example, the fibers P are drawn onto the drawing roller 14 and then wound onto the winding roller 15. In other embodiments, the fibers P may also initially be drawn onto a feed roller (not shown) before traversing to the drawing roller 14 and winding roller 15. Regardless, the drawing roller 14 may operate at any desired speed, such as from about 200 to about 3,000 meters per minute (m/min), in some embodiments from about 300 to about 2,000 m/min, and in some embodiments, from about 400 to about 1,200 m/min. The fibers may be drawn at any desired draw ratio depending on the desired properties. In this regard, the fibers may be drawn from about 1.1× to about 6×, in some embodiments from about 1.2× to about 5×, and in some embodiments, from about 1.5× to about 4×.

As noted above, the fibers may also be subjected to heat treatment during and/or after their formation, such as to increase the molecular weight of the liquid crystal polymer. For example, the liquid crystalline polymer within the composition supplied to the extruder 11 may be only melt-polymerized or solid-state polymerized to a relatively low degree in the manner described above. After the composition is formed into fibers, the liquid crystalline polymer may subjected to heat treatment to solid-stated polymerize the polymer as described to achieve the desired molecular weight. In one embodiment, for example, the “as-spun” fibers may be subjected to heat treatment (e.g., in an oven) after they are wound onto the winding roller 15. Such heat treatment typically occurs at a temperature of from about 330° C. to about 400° C., and in some embodiments, from about 340° C. to about 380° C. The heat treatment may occur for a time period of from about 0.5 to about 50 hours, and in some embodiments, from about 1 to about 20 hours, preferably in an inert atmosphere, such as nitrogen and argon.

Monofilaments and multifilaments may be formed using the general process described above as is known in the art. Such fibers may have a particular cross-section as dictated by the spinneret design. Generally, the fibers may have an axial core extending along the continuous length direction of the fiber. In this regard, the axial core may comprise the polymer composition as defined herein in one embodiment. In another embodiment, the axial core of the fiber may be hollow, such that it does not include the polymer composition as defined herein. In one embodiment, the fiber may generally have a circular cross-section. In another embodiment, the fiber may generally have a non-circular cross-section. For instance, the fiber may generally have an oval-shaped cross section. However, it should be understood that other non-circular cross-sections may also be formed from the polymer as disclosed herein. In another embodiment, the fiber may be multilobal. For instance, the fiber may include two or more lobes. Such lobes may be radially disposed from the axial core. In this regard, the lobes may extend from a central portion or axial core of a fiber wherein each lobe has a proximal end adjacent the central portion and a distal end radially spaced apart from the proximal end. Furthermore, each lobe may have a convex curve. In this regard, each lobe may be free of a relatively flat surface. Furthermore, each lobe may be directly connected to one another in one embodiment. In this regard, such connection point between adjacent lobes may be referred to as a cusp. Alternatively, adjacent lobes may not be directly connected. Such an area connecting two adjacent lobes may be referred to as a lobe connection. Such lobe connections may also have a relatively convex curve. Similar to the lobes, such lobe connections may also be free of a relatively flat surface. In addition, the lobes may be positioned symmetrically about the fiber. In other words, the fiber may have a symmetrical cross-section in one embodiment. In another embodiment, the fiber may have an asymmetrical cross-section. Also, the lobes may be asymmetrical or symmetrical. In one embodiment, the lobes may be asymmetrical. In another embodiment, the lobes may be symmetrical. In embodiments in which the yarn is a multifiber yarn, the yarn may contain at least 2 fibers, in some embodiments from 3 to 100 fibers, and in some embodiments, from 4 to 50 fibers. In such embodiments, any number of the fibers may be formed from the polymer composition. For example, the yarn may contain only fibers formed from the polymer composition described herein, or it may contain one or more fibers formed from the polymer composition and one or more fibers formed from other types of polymer compositions.

Regardless of their particular type, a yarn may optionally be formed from the fibers, which may or may not involve further processing of the fibers. For example, the fibers may be converted into a textured yarn through known false twist texturing conditions or other processes. It may also be desirable to increase the surface area of the fibers to provide a softer feel and to enhance the ability of the fibers to breathe, thereby providing better insulation and water retention in the case of textiles. To increase the surface area, the fiber may be crimped or twisted, such as by a false twist method, an air jet, an edge crimp, a gear crimp, a stuffer box, etc. for example. To help improve adhesion to other materials (e.g., conductive layer of a laminate), a finish may also be applied to the fibers, before and/or after heat treatment. Examples of such finishes may include, for instance, carboxylic acid derivatives (e.g., trimethyolethane tripelargonate), epoxy derivatives (e.g., glycerol epoxide, sorbitol epoxy, etc.), polyols (e.g., pentaerythritol, sorbitol, arabitol, mannitol, dipentaerythritoltrimethylolpropane, penta (ethylene glycol), neopentylglycol etc.), carboxylic acid derivatives of polyols (e.g., pentaerythritol tetraisostearate, pentaerythritol tetrapelargonate, pentaerythritol tetraoctanoate, pentaerythritol tetralaurate, pentaerythritol tetrastearate, pentaerythritol tetrabenzoate, etc.).

The resulting yarn may have a total denier of from about 100 to about 3,000, in some embodiments from about 150 to about 2,500, and in some embodiments, from about 200 to about 2,250. The yarn may also have a linear density of from about 100 to about 3,000 denier per filament (dpf), in some embodiments from about 150 to about 2,500 dpf, and in some embodiments, from about 200 to about 2,500 dpf. The denier and linear density may be determined in accordance with ASTM D1907/D1907M-12 (2018) at a temperature of about 23° C. At least in part due to the beneficial properties of the polymer composition described herein, the yarn may also exhibit certain desired properties that allow it to be used for various applications, such as in a laminate for a printed circuit board. For example, the elongation at break of the yarn may range from about 1% to about 10%, in some embodiments from about 2% to about 8%, and in some embodiments, from about 2.5% to about 6%, such as determined in accordance with ASTM D2256/D2256M-21 at a temperature of about 23° C. The breaking tenacity of the yarn may also be relatively high, such as from about 10 to about 60 grams per denier (g/d), in some embodiments from about 15 to about 50 g/d, and in some embodiments, from about 20 to about 40 g/d, such as determined in accordance with ASTM D2256/D2256M-21 at a temperature of about 23° C. In addition, even with a relatively high elongation at break and tenacity, the yarn may nonetheless exhibit a relatively low shrinkage, such as about 1% or less, in some embodiments about 0.5% or less, and in some embodiments, from about 0.01% to about 0.2%, as determined in dry air at 177° C. for 30 minutes in accordance with ASTM D2259-02 (2016).

### III. Fibrous Substrate

The advantageous properties of the fibers (and yarns formed from the fibers) as disclosed herein can allow for them to be utilized in various types of fibrous substrates, such as woven fabrics, knit fabrics, nonwoven webs, etc., which can be prepared using conventional techniques including, but not limited to, weaving, knitting, meltblowing, spunbonding, carding and heat bonding (e.g., hot air and point bonding), etc. In one particular embodiment, for example, the yarns described herein may be used to form a “woven fabric” using techniques that are well known in the art. For example, such fabrics may be made by formed by interlacing of two sets of yarn called warp yarns (warp) and weft yarns (weft). Warp runs in the fabric in a length-wise direction and weft yarns runs in the fabric in a width-wise direction. The fabrics are woven by known techniques, such as plain weave, satin weave, and twill weave techniques. The yarns described herein may be used to form some or all of the weft yarns, warp yarns, and/or both types of yarns in the woven fabric.

If desired, the fibrous substrate may be impregnated with a resin to form a “composite.” In such embodiments, any suitable impregnating resin may be employed, such as epoxy resins, polyphenyl ethers, acrylates, cyano-acrylates, cyano-esters, urethanes, liquid crystalline polymers (e.g., thermosetting polymers), etc. One particular example of such a resin is an epoxy resin, which typically contains an epoxide and a curing agent. The epoxide may include an organic compound having at least one oxirane ring polymerizable by a ring opening reaction, and can be aliphatic, heterocyclic, cycloaliphatic, and/or aromatic. The epoxide may be a “polyepoxide” in that it contains at least two epoxy groups per molecule, and it may be monomeric, dimeric, oligomeric or polymeric in nature. The backbone of the resin may be of any type, and substituent groups thereon can be any group not having a nucleophilic group or electrophilic group (such as an active hydrogen atom) which is reactive with an oxirane ring. Exemplary substituent groups include halogens, ester groups, ethers, sulfonate groups, siloxane groups, nitro groups, amide groups, nitrile groups, and phosphate groups. Suitable epoxide resins may include, for instance, the reaction product of bisphenol A and epichlorohydrin, the reaction product of phenol and formaldehyde (novolac resin) and epichlorohydrin, peracid epoxies, glycidyl esters, glycidyl ethers, the reaction product of epichlorohydrin and p-amino phenol, the reaction product of epichlorohydrin and glyoxal tetraphenol, etc. Particularly suitable epoxides have the general structure set forth below in general formula (I):

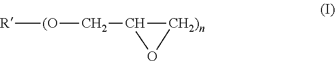

wherein n is 1 or more, and in some embodiments, from 1 to 4, and R′ is an organic residue that may include, for example, an alkyl group, an alkyl ether group, or an aryl group; and n is at least 1. For example, R′ may be a poly(alkylene oxide). Suitable glycidyl ether epoxides of formula (I) include glycidyl ethers of bisphenol A and F, aliphatic diols or cycloaliphatic diols. The glycidyl ether epoxides may include linear polymeric epoxides having terminal epoxy groups (e.g., a diglycidyl ether of polyoxyalkylene glycol) and aromatic glycidyl ethers (e.g., those prepared by reacting a dihydric phenol with an excess of epichlorohydrin). Examples of dihydric phenols include resorcinol, catechol, hydroquinone, and the polynuclear phenols including p,p′-dihydroxydibenzyl, p,p′-dihydroxyphenylsulfone, p,p′-dihydroxybenzophenone, 2,2′-dihydroxyphenyl sulfone, p,p′-dihydroxybenzophenone, 2,2-dihydroxy-1,1-dinaphrhylmethane, and the 2,2′, 2,3′, 2,4′, 3,3′, 3,4′, and 4,4′ isomers of dihydroxydiphenylmethane, dihydroxydiphenyldimethylmethane, dihydroxydiphenylethylmethylmethane, dihydroxydiphenylmethylpropylmethane, dihydroxydiphenylethylphenylmethane, dihydroxydiphenylpropylenphenylmethane, dihydroxydiphenylbutylphenylmethane, dihydroxydiphenyltolylethane, dihydroxydiphenyltolylmethylmethane, dihydroxydiphenyldicyclohexylmethane, and dihydroxydiphenylcyclohexane.

The epoxy resin may also include a curing agent capable of cross-linking the epoxide, such as room temperature curing agents, heat-activated curing agents, etc. Examples of such curing agents may include, for instance, imidazoles, imidazole-salts, imidazolines, tertiary amine, and/or primary or secondary amines, such as diamine, diethylene diamine, diethylene triamine, triethylene tetramine, propylene diamine, tetraethylene pentamine, hexaethylene heptamine, hexamethylene diamine, 2-methyl-1,5-pentamethylene-diamine, 4,7,10-trioxatridecan-1,13-diamine, aminoethylpiperazine, etc. In certain embodiments, the curing agent is a polyether amine having one or more amine moieties, including those polyether amines that can be derived from polypropylene oxide or polyethylene oxide.

The manner in which an impregnating resin is incorporated into the fibrous substrate may vary as is known by those skilled in the art. For example, in certain embodiments, the fibrous substrate may be formed and thereafter contacted with the impregnating resin, such as by dipping, powder coating, spraying, etc. In one particular embodiment, the polymer composition may be applied using a thermal spraying method, such as flame spraying, cold spraying, warm spraying, plasma spraying, etc. Thermal spraying generally involves the use of a working gas that is heated to a temperature lower than the melting point or softening temperature of the polymer composition. The gas is accelerated to supersonic velocity so that the composition is brought into collision with the substrate at a high velocity to form a coating thereon. During this process, the resin may be heated to a certain temperature (e.g., above the melting temperature). The resin may be supplied to the working gas along the coaxial direction with the gas at a feed rate, such as from about 1 to about 200 g/minute, and in some embodiments, from about 10 to about 100 g/minute. The distance between the substrate and the nozzle tip of the spray apparatus may be from about 5 to about 100 mm, and the traverse velocity of the nozzle may be from about 10 to about 300 min/second.

Once impregnated, the resin may be crosslinked to form a thermoset polymer. Crosslinking may occur at temperatures of about 380° C. or more, in some embodiments about 390° C. or more, and in some embodiments, 400° C. to about 450° C. It should of course be understood that the resin may also be formed by crosslinking prior to forming the composite, if so desired.

### IV. Laminate

As indicated above, the fibrous substrate (optionally impregnated with a resin) may be laminated to a conductive layer or to other laminate materials containing a conductive layer. The conductive layer may be in the form of a metal plate or foil, such as those containing gold, silver, copper, nickel, aluminum, etc. (e.g., copper foil). The fibrous substrate may be laminated to the conductive layer using any known technique, such as ion beam sputtering, high frequency sputtering, direct current magnetron sputtering, glow discharge, etc.

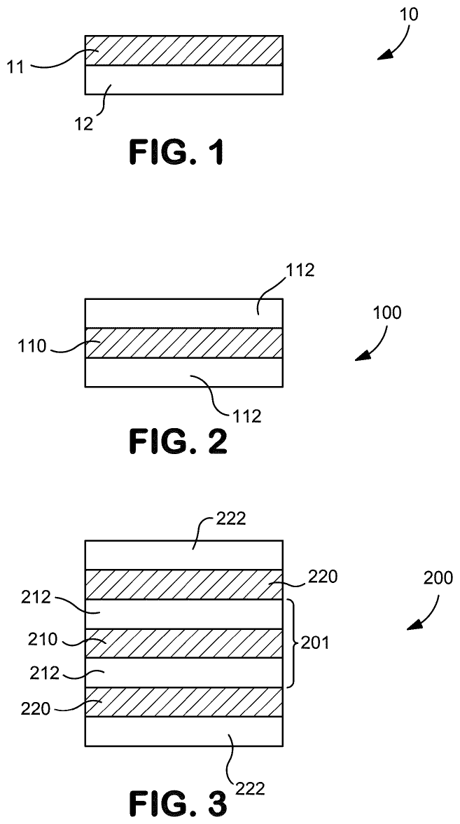

The laminate may have a two-layer structure containing only the fibrous substrate and conductive layer. Referring to FIG. 1, for example, one embodiment of such a two layer structure 10 is shown as containing a fibrous substrate 11 positioned adjacent to a conductive layer 12 (e.g., copper foil). Alternatively, a multi-layered laminate may be formed that contains two or more conductive layers and/or two or more fibrous substrate layers. Referring to FIG. 2, for example, one embodiment of a three-layer laminate structure 100 is shown that contains a fibrous substrate 110 positioned between two conductive layers 112. Yet another embodiment is shown in FIG. 3. In this embodiment, a seven-layered laminate structure 200 is shown that contains a core 201 formed from an insulating layer 210 positioned between two conductive layers 212. Insulating layers 220 likewise overlie each of the conductive layers 212, respectively, and external conductive layers 222 overlie insulating layers 220. In the embodiments described above, the fibrous substrate of the present invention may be used to form any, or even all of the insulating layers. Further, the layers in the aforementioned embodiments may be attached together using techniques well known in the art, such as through the use of an adhesive. Various conventional processing steps may also be employed to provide the laminate with sufficient strength. For example, the laminate may be pressed and/or subjected to heat treatment as is known in the art.

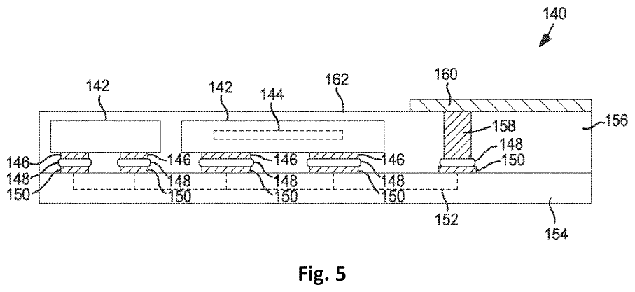

The laminate of may be employed in a wide variety of different applications and is particularly useful in areas in which heat resistance and high frequency performance are of importance, such as in printed circuit boards (e.g., rigid or rigid-flex), shields for electromagnetic waves, communication equipment circuits, MEMS devices, semiconductor packaging, etc. In one particular embodiment, for instance, the fibrous substrate is employed in a printed circuit board of an electronic device. In certain embodiments, the electronic device may be provided with antenna elements. The antenna elements may be applied (e.g., printed) directly onto the circuit board, or alternatively they may be provided in an antenna module that is supported by and connected to the circuit board. Referring to FIG. 5, for instance, one embodiment of an electronic device 140 is shown that contains a substrate 154 that supports various electrical components 142, such as integrated circuits (e.g., transceiver circuitry, control circuitry, etc.), discrete components (e.g., capacitors, inductors, resistors), switches, and so forth. An encapsulant material 156 may be be applied over the components 142 and a printed circuit board 154, such as described herein, that contains conductive traces 152 and contact pads 150 for forming electrical signal paths. A semiconductor die 144 may also be employed that is bonded to the printed circuit board and embedded within the package body to form each respective component 142. More particularly, the components 142 may have contacts 146 (e.g., solder pads) and may be mounted to contacts 150 on the printed circuit board 154 using a conductive material 148 (e.g., solder) coupled between contacts 146 and contacts 150. In the illustrated embodiment, antenna elements 160 are formed on an exposed surface of the encapsulant material 156. The antenna elements 156 may be electrically connected to the printed circuit board 154 via a transmission line 158 (e.g. metal post).

In certain embodiments, the printed circuit board is specifically configured for use in a 5G antenna system. As used herein, “5G” generally refers to high speed data communication over radio frequency signals. 5G networks and systems are capable of communicating data at much faster rates than previous generations of data communication standards (e.g., “4G, “LTE”). Various standards and specifications have been released quantifying the requirements of 5G communications. As one example, the International Telecommunications Union (ITU) released the International Mobile Telecommunications−2020 (“IMT-2020”) standard in 2015. The IMT-2020 standard specifies various data transmission criteria (e.g., downlink and uplink data rate, latency, etc.) for 5G. The IMT-2020 Standard defines uplink and downlink peak data rates as the minimum data rates for uploading and downloading data that a 5G system must support. The IMT-2020 standard sets the downlink peak data rate requirement as 20 Gbit/s and the uplink peak data rate as 10 Gbit/s. As another example, 3^{rd} Generation Partnership Project (3GPP) recently released new standards for 5G, referred to as “5G NR.” 3GPP published “Release 15” in 2018 defining “Phase 1” for standardization of 5G NR. 3GPP defines 5G frequency bands generally as “Frequency Range 1” (FR1) including sub-6 GHZ frequencies and “Frequency Range 2” (FR2) as frequency bands ranging from 20-60 GHz. However, as used herein “5G frequencies” can refer to systems utilizing frequencies greater than 60 GHz, for example ranging up to 80 GHz, up to 150 GHz, and up to 300 GHz. As used herein, “5G frequencies” can refer to frequencies that are about 2.5 GHz or higher, in some embodiments about 3.0 GHz or higher, in some embodiments from about 3 GHz to about 300 GHz, or higher, in some embodiments from about 4 GHz to about 80 GHz, in some embodiments from about 5 GHz to about 80 GHZ, in some embodiments from about 20 GHz to about 80 GHz, and in some embodiments from about 28 GHz to about 60 GHz.

5G antenna systems generally employ high frequency antennas and antenna arrays for use in base stations, repeaters (e.g., “femtocells”), relay stations, terminals, user devices, and/or other suitable components of 5G systems. The antenna elements/arrays and systems can satisfy or qualify as “5G” under standards released by 3GPP, such as Release 15 (2018), and/or the IMT-2020 Standard. To achieve such high speed data communication at high frequencies, antenna elements and arrays generally employ small feature sizes/spacing (e.g., fine pitch technology) and/or advanced materials that can improve antenna performance. For example, the feature size (spacing between antenna elements, width of antenna elements) etc. is generally dependent on the wavelength (“λ”) of the desired transmission and/or reception radio frequency propagating through the circuit board on which the antenna element is formed (e.g., nλ/4 where n is an integer). Further, beamforming and/or beam steering can be employed to facilitate receiving and transmitting across multiple frequency ranges or channels (e.g., multiple-in-multiple-out (MIMO), massive MIMO). The high frequency 5G antenna elements can have a variety of configurations. For example, the 5G antenna elements can be or include co-planar waveguide elements, patch arrays (e.g., mesh-grid patch arrays), other suitable 5G antenna configurations. The antenna elements can be configured to provide MIMO, massive MIMO functionality, beam steering, etc. As used herein “massive” MIMO functionality generally refers to providing a large number transmission and receiving channels with an antenna array, for example 8 transmission (Tx) and 8 receive (Rx) channels (abbreviated as 8×8). Massive MIMO functionality may be provided with 8×8, 12×12, 16×16, 32×32, 64×64, or greater.

The antenna elements may be fabricated using a variety of manufacturing techniques. As one example, the antenna elements and/or associated elements (e.g., ground elements, feed lines, etc.) can employ fine pitch technology. Fine pitch technology generally refers to small or fine spacing between their components or leads. For example, feature dimensions and/or spacing between antenna elements (or between an antenna element and a ground plane) can be about 1,500 micrometers or less, in some embodiments 1,250 micrometers or less, in some embodiments 750 micrometers or less (e.g., center-to-center spacing of 1.5 mm or less), 650 micrometers or less, in some embodiments 550 micrometers or less, in some embodiments 450 micrometers or less, in some embodiments 350 micrometers or less, in some embodiments 250 micrometers or less, in some embodiments 150 micrometers or less, in some embodiments 100 micrometers or less, and in some embodiments 50 micrometers or less. However, it should be understood that feature sizes and/or spacings that are smaller and/or larger may also be employed. As a result of such small feature dimensions, antenna configurations and/or arrays can be achieved with a large number of antenna elements in a small footprint. For example, an antenna array can have an average antenna element concentration of greater than 1,000 antenna elements per square centimeter, in some embodiments greater than 2,000 antenna elements per square centimeter, in some embodiments greater than 3,000 antenna elements per square centimeter, in some embodiments greater than 4,000 antenna elements per square centimeter, in some embodiments greater than 6,000 antenna elements per square centimeter, and in some embodiments greater than about 8,000 antenna elements per square centimeter. Such compact arrangement of antenna elements can provide a greater number of channels for MIMO functionality per unit area of the antenna area. For example, the number of channels can correspond with (e.g., be equal to or proportional with) the number of antenna elements.

The present invention may be better understood with reference to the following examples and test methods.

### Test Methods

Melt Viscosity: The melt viscosity (Pa-s) may be determined in accordance with ISO 11443:2021 at a shear rate of 400 or 1,000 s⁻¹ and temperature 15° C. above the melting temperature using a Dynisco LCR7001 capillary rheometer. The rheometer orifice (die) may have a diameter of 1 mm, length of 20 mm, L/D ratio of 20.1, and an entrance angle of 180°. The diameter of the barrel may be 9.55 mm+0.005 mm and the length of the rod may be 233.4 mm.

Melting Temperature: The melting temperature (“Tm”) may be determined by differential scanning calorimetry (“DSC”) as is known in the art. The melting temperature is the differential scanning calorimetry (DSC) peak melt temperature as determined by ISO 11357-3:2018. Under the DSC procedure, samples were heated and cooled at 20° C. per minute as stated in ISO Standard 10350 using DSC measurements conducted on a TA Q2000 Instrument.

Deflection Temperature Under Load (“DTUL”): The deflection under load temperature may be determined in accordance with ISO 75-2:2013 (technically equivalent to ASTM D648). More particularly, a test strip sample having a length of 80 mm, thickness of 10 mm, and width of 4 mm may be subjected to an edgewise three-point bending test in which the specified load (maximum outer fibers stress) was 1.8 Megapascals. The specimen may be lowered into a silicone oil bath where the temperature is raised at 2° C. per minute until it deflects 0.25 mm (0.32 mm for ISO 75-2:2013).

Tensile Modulus, Tensile Stress, and Tensile Elongation: Tensile properties may be tested according to ISO 527:2019 (technically equivalent to ASTM D638). Modulus and strength measurements may be made on the same test strip sample having a length of 80 mm, thickness of 10 mm, and width of 4 mm. The testing temperature may be 23° C., and the testing speeds may be 1 or 5 mm/min.

Flexural Modulus, Flexural Stress, and Flexural Elongation: Flexural properties may be tested according to ISO 178:2019 (technically equivalent to ASTM D790). This test may be performed on a 64 mm support span. Tests may be run on the center portions of uncut ISO 3167 multi-purpose bars. The testing temperature may be 23° C. and the testing speed may be 2 mm/min.

Dielectric Constant (“Dk”) and Dissipation Factor (“Df”): The dielectric constant (or relative static permittivity) and dissipation factor are determined using a known split-post dielectric resonator technique, such as described in Baker-Jarvis, et al., IEEE Trans. on Dielectric and Electrical Insulation, 5 (4), p. 571 (1998) and Krupka, et al., Proc. 7^{th} International Conference on Dielectric Materials: Measurements and Applications, IEEE Conference Publication No. 430 (September 1996). More particularly, a plaque sample having a size of 80 mm×90 mm×3 mm or a disc sample having a 4-inch and 3-mm thickness may be inserted between two fixed dielectric resonators. The resonator measured the permittivity component in the plane of the specimen. Five (5) samples are tested and the average value is recorded. The split-post resonator can be used to make dielectric measurements in the low gigahertz region, such as 2 GHz or 10 GHz.

### Example 1

A polymer composition was formed that contains 100 wt. % of a liquid crystalline polymer formed from 48% HNA, 2% HBA, 25% NDA, and 25% BP. The composition had a dielectric constant of 3.48 (10 GHZ), dissipation factor of 0.0006 (10 GHZ), melting temperature of 329° C., and deflection temperature under load of 234° C. (1.8 MPa). In addition, the composition exhibited a tensile strength of 160 MPa, tensile modulus of 7,332 MPa, tensile elongation of 2.71%, flexural strength of 159 MPa, flexural modulus of 7,678 MPa, and Charpy notched impact strength of 43.5 KJ/m². The polymer composition was then spun into monofilaments (15 dpf and 10 dpf) and various tensile properties were measured using an Instron tensile tester (gauge length 200 mm, tensile speed 50 mm/min). The “as spun” 15 dpf filaments had a strength of 6.6 grams per denier, elongation of 1.47%, and elastic modulus of 551.8 grams per denier. The “as spun” 10 dpf filaments had a strength of 6.3 grams per denier, elongation of 1.49%, and elastic modulus of 547.4 grams per denier.

### Example 2

A polymer composition for spinning into fibers was formed that contains 100 wt. % of a liquid crystalline polymer formed from 48% HNA, 2% HBA, 23% NDA, 25% BP, and 2% TA. The composition had a dielectric constant of 3.41 (10 GHZ), dissipation factor of 0.0006 (10 GHZ), melting temperature of 337° C., and deflection temperature under load of 279° C. (1.8 MPa). In addition, the composition exhibited a tensile strength of 149 MPa, tensile modulus of 11,737 MPa, tensile elongation of 1.69%, flexural strength of 214 MPa, flexural modulus of 12,241 MPa, and Charpy notched impact strength of 53.9 KJ/m².

### Example 3

A polymer composition for spinning into fibers was formed that contains 100 wt. % of a liquid crystalline polymer formed from 20% HNA, 79.3% HBA, and 0.7% TA. The composition had a dielectric constant of 3.36 (10 GHZ), dissipation factor of 0.0017 (10 GHZ), melting temperature of 325° C., and deflection temperature under load of 175° C. (1.8 MPa). In addition, the composition exhibited a tensile strength of 150 MPa, tensile modulus of 8,200 MPa, tensile elongation of 3.7%, flexural strength of 145 MPa, and flexural modulus of 7,300 MPa.

### Example 4

A polymer composition for spinning into fibers was formed that contains 100 wt. % of a liquid crystalline polymer formed from 76% HNA and 24% HBA. The composition had a dielectric constant of 3.41 (10 GHZ), dissipation factor of 0.001 (10 GHZ), melting temperature of 330° C., and deflection temperature under load of 208° C. (1.8 MPa). In addition, the composition exhibited a tensile strength of 160 MPa, tensile modulus of 8,720 MPa, tensile elongation of 2.12%, flexural strength of 175 MPa, flexural modulus of 8,926 MPa, and Charpy notched impact strength of 52.6 KJ/m².

### Example 5

A polymer composition for spinning into fibers was formed that contains 100 wt. % of a liquid crystalline polymer formed from 50% HNA, 25% NDA, and 25% BP. The composition had a dielectric constant of 3.48 (10 GHZ), dissipation factor of 0.0007 (10 GHZ), melting temperature of 330° C., and deflection temperature under load of 254° C. (1.8 MPa). In addition, the composition exhibited a tensile strength of 133 MPa, tensile modulus of 6,789 MPa, tensile elongation of 2.78%, flexural strength of 155 MPa, flexural modulus of 6,975 MPa, and Charpy notched impact strength of 43.2 KJ/m².

These and other modifications and variations of the present invention may be practiced by those of ordinary skill in the art, without departing from the spirit and scope of the present invention. In addition, it should be understood that aspects of the various embodiments may be interchanged both in whole or in part. Furthermore, those of ordinary skill in the art will appreciate that the foregoing description is by way of example only, and is not intended to limit the invention so further described in such appended claims.

1. A laminate comprising a fibrous substrate and a conductive layer positioned adjacent to the fibrous substrate, wherein the fibrous substrate is formed from fibers that include a polymer composition, wherein the polymer composition contains a liquid crystalline polymer, and further wherein the polymer composition has a melting temperature of from about 300° C. to about 400° C. as determined in accordance with ISO 11357-3:2018 and a dissipation factor of about 0.005 or less at a frequency of 10 GHz.

2. The laminate of claim 1, wherein the polymer composition exhibits a dielectric constant of about 5 or less as determined at a frequency of 10 GHz.

3. The laminate of claim 1, wherein the polymer composition exhibits a dissipation factor of about 0.001 or less at a frequency of 10 GHz.

4. The laminate of claim 1, wherein the polymer composition exhibits a deflection temperature under load of about 200° C. to about 350° C., as determined in accordance with ISO 75-2:2013 at 1.8 MPa.

5. The laminate of claim 1, wherein the liquid crystalline polymer contains from 0 mol. % to about 5 mol. % of a repeating unit represented by Formula (I), from about 20 mol. % to about 70 mol. % of a repeating unit represented by Formula (II), from about 5 mol. % to about 50 mol. % of a repeating unit represented by Formula (III), from about 5 mol. % to about 50 mol. % of a repeating unit represented by Formula (IV), and from 0 mol. % to about 5 mol. % of a repeating unit represented by Formula (V),
—O—Ar¹—CO— (I)
—O—Ar²—CO— (II)
—CO—Ar³—CO— (III)
—O—Ar⁴—O— (IV)
—CO—Ar³⁵—CO— (V)
wherein Ar¹, Ar⁴, and Ar⁵ independently represent a phenyl or a biphenyl group, optionally substituted with a halogen atom, an alkyl group having 1 to 10 carbon atoms, or an aryl group having 6 to 20 carbon atoms, and further wherein Ar² and Ar³ independently represent a naphthenyl group optionally substituted with a halogen atom, an alkyl group having 1 to 10 carbon atoms, or an aryl group having 6 to 20 carbon atoms.

6. The laminate of claim 5, wherein the liquid crystalline polymer includes from about 35 mol. % to about 60 mol. % of a repeating unit represented by Formula (II), from about 10 mol. % to about 40 mol. % of a repeating unit represented by Formula (III), and from about 10 mol. % to about 40 mol. % of a repeating unit represented by Formula (IV).

7. The laminate of claim 6, wherein the liquid crystalline polymer includes from about 0.1 mol. % to about 5 mol. % of a repeating unit represented by Formula (I) and/or from 0.1 mol. % to about 5 mol. % of a repeating unit represented by Formula (V).

8. The laminate of claim 6, wherein the total molar percentage of the repeating units represented by Formulae (I), (II), (III), (IV), and (V) equals 100%.

9. The laminate of claim 6, wherein the repeating unit represented by Formula (II) is derived from 6-hydroxy-2-naphthoic acid and the repeating unit represented by Formula (III) is 2,6-naphthalenedicarboxylic acid.

10. The laminate of claim 9, wherein the repeating unit represented by Formula (I) is derived from 4-hydroxybenzoic acid.

11. The laminate of claim 9, wherein the repeating unit represented by Formula (IV) is derived from 4,4′-biphenol.

12. The laminate of claim 9, wherein the repeating unit represented by Formula (V) is derived from terephthalic acid.

13. The laminate of claim 1, wherein the fibrous substrate includes a fabric formed from a yarn, wherein the yarn contain the fibers.

14. The laminate of claim 1, wherein the fibrous substrate includes a woven fabric.

15. The laminate of claim 1, wherein the fibrous substrate includes a knitted fabric.

16. The laminate of claim 1, wherein the fibrous substrate includes a nonwoven web.

17. The laminate of claim 1, wherein the conductive layer contains copper.

18. The laminate of claim 1, wherein the fibrous substrate is positioned between two conductive layers.

19. The laminate of claim 1, wherein the fibrous substrate is impregnated with a resin.

20. A printed circuit board comprising the laminate of claim 1.
